(19) United States
(12) Patent Application Publication
(10) Pub. No.: US 2011/0075331 A1
(43) Pub. Date: Mar. 31, 2011

(54) Media Player Holder

(76) Inventors: Nigel Greig, Auckland (NZ); Edward Scholten, Auckland (NZ)

(21) Appl. No.: 12/773,633

(22) Filed: May 4, 2010

Related U.S. Application Data
(60) Provisional application No. 61/175,230, filed on May 4, 2009.

(51) Int. Cl. H05K 7/00

(52) U.S. Cl. 361/679.01

(57) ABSTRACT

A docking station for a media player, comprising a body having adjustable securing apparatus to allow a plurality of individual media players of different dimensions to be selectively secured to the body.

### CROSS REFERENCE TO RELATED APPLICATIONS

This application claims priority to and the benefit of U.S. Provisional Application No. 61/175,230, filed May 4, 2009, which is incorporated herein by reference.

### FIELD OF THE INVENTION

This invention relates to a holding mechanism and/or a docking station for a media player.

### BACKGROUND

Media player devices such as those commonly referred to as “MP3” or “MP4” players are becoming increasingly popular. Users tend to store personalized selections of their favorite media entertainment, for example music playlists, on such media players. Users now expect to be able to use their players in environments such as aircraft, and there is a demand for appropriate connections in these environments to at least power or recharge media players, and to allow media players to communicate with other systems such as In Flight Entertainment (IFE) systems.

Existing docking stations are typically configured for a single media player product and are therefore not suited to accommodating the many different player designs presently on the market.

### SUMMARY

It is an object of the invention to overcome or ameliorate one or more disadvantages of known systems. Another object is to provide a holding mechanism or docking station that will receive media players of different types or dimensions.

Accordingly one embodiment of the disclosed subject matter provides a docking station for a media player, comprising a body having adjustable securing apparatus to allow a plurality of individual media players of different dimensions to be selectively secured to the body.

In one embodiment the body or the securing apparatus allow a media player to be electrically coupled to the docking station.

In one embodiment the securing apparatus comprises a clamp.

In one embodiment the securing apparatus is rotatable relative to the body to allow a media player to be disposed at a desired angular orientation relative to the body.

In one embodiment the docking station includes a controller.

In one embodiment the docking station includes a display screen. In another embodiment the docking station communicates with a remote display.

In one embodiment the docking station includes shock absorption apparatus to facilitate operation in a transport environment such as an aircraft.

In one embodiment the disclosed subject matter includes a passenger seat having a recess in which the docking station is provided.

In one embodiment the docking station comprises a universal docking station.

### DRAWING DESCRIPTION

One or more embodiments of the invention will be described below, by way of example, with reference to the accompanying drawings in which:

FIG. 1 is an isometric view of a first embodiment of a media player docking station.

FIG. 2 is an isometric view of a further embodiment of a media player docking station.

FIG. 3 is an isometric view of a still further embodiment of a media player docking station.

FIGS. 4 and 5 are isometric views of a docking station according to the embodiment of FIG. 2, showing the docking station without a media player.

FIGS. 5 to 10 are isometric views of a docking station according to the embodiment of FIGS. 2, 4 and 5, showing the docking station being used to hold different sized media players in selected orientations.

### DETAILED DESCRIPTION

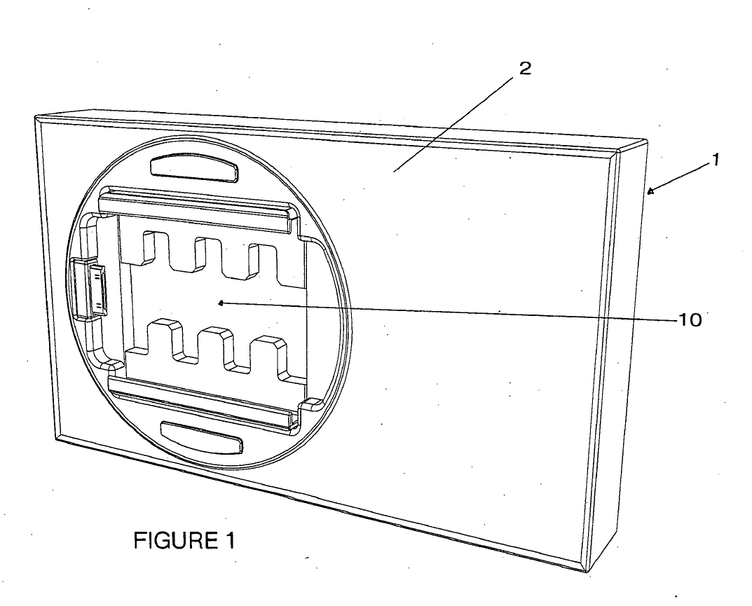

Referring to FIG. 1, media player holding apparatus which will be referred to in this document as a docking station, is shown, generally referenced 1. The docking station 1 has a housing or body 2 which is adapted to fit in use into a recess in the back of a passenger seat, such as an aircraft seat. In one embodiment, the body 2 is adapted to fit into an industry standard sized recess in the back of an aircraft passenger seat. Thus in one embodiment the docking station is provided in the rear of a passenger seat so that a passenger in the seat immediately behind the seat in which the docking station is provided may have convenient access to the docking station.

In one embodiment shock absorption apparatus, such as a layer or bed of vibration damping material, is provided between the body 2 and the passenger seat. Alternatively the shock absorption apparatus may be provided between the body and a base plate 20, or between clamping members 24 and base plate 20. In other embodiments shock absorption apparatus may be provided on parts of the docking station (for example surfaces of clamping members 24) that contact or support the media player.

The body 2 supports media player securing apparatus which is generally referenced 10 in FIG. 1, and which is described in more detail below.

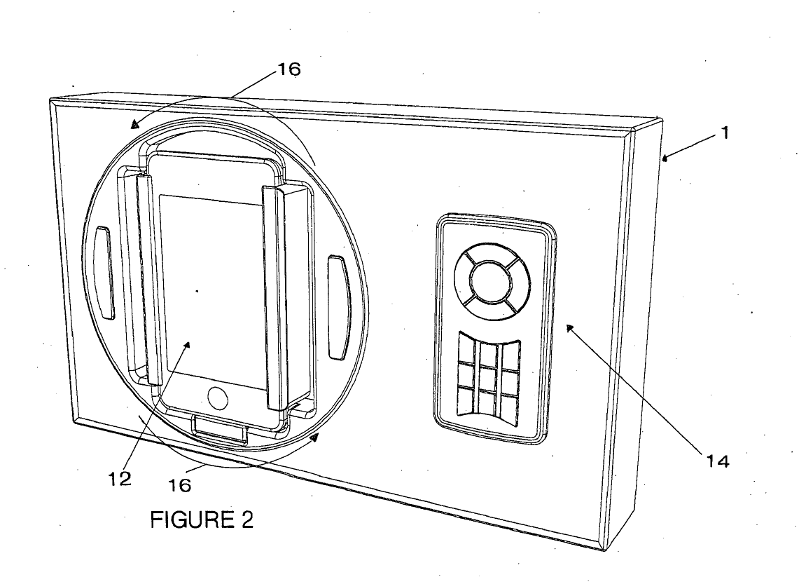

Referring now to FIG. 2, another embodiment of the docking station 1 is shown. In this embodiment the securing apparatus 10 is the same as that of the embodiment shown in FIG. 1, but the FIG. 2 embodiment shows the securing apparatus being used to hold a media player 12. The FIG. 2 embodiment further includes a controller 14 that allows a user to control the media player, so that the user does not need to remove the media player from the securing apparatus to change play settings or media selections.

As can be seen from arrows 16, the securing apparatus 10 is rotatably mounted relative to the body 2. In use this allows a media player secured by apparatus 10 to be oriented in a desired manner for ease of use or viewing by a user.

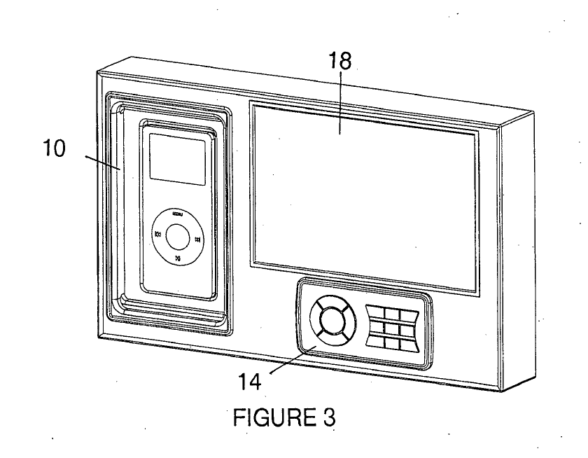

Referring now to FIG. 3, a still further embodiment of docking station 1 is shown in which a display 18 is included in body 2. In this embodiment the securing apparatus 10 is not rotatable, but could be substituted with the rotatable securing apparatus of the embodiments described above. Those skilled in the art will appreciate that features of the embodiments described may be assembled in different combinations.

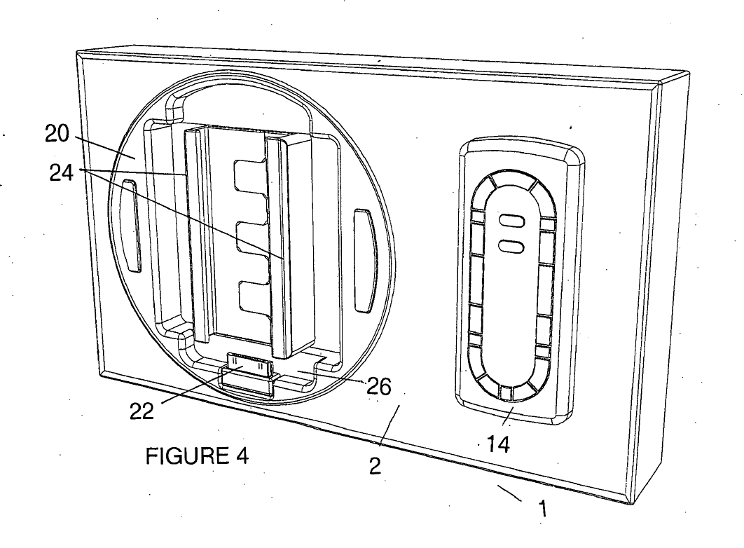

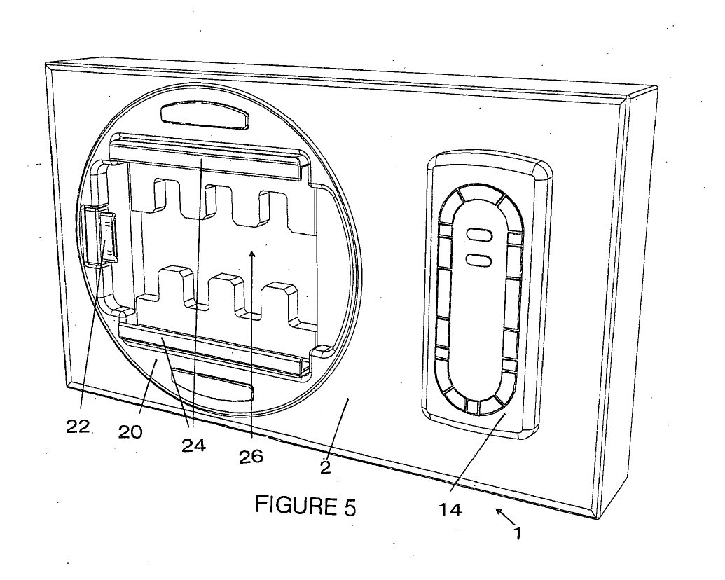

Turning now to FIGS. 4 and 5, the securing apparatus 10 is shown in greater detail. The apparatus is supported by base plate 20 which in the embodiment shown is rotatable relative to the body 2. Base plate 20 includes a recess generally referenced 26 for receiving the media player. An electrical connector 22 is provided in recess 26 for electrically associating the media player with the docking station. In one embodiment the connector 22 may simply be used to provide power to the media player. In other embodiments the connector 22 may be used to alternatively or additionally allow the media player to communicate with the docking station and/or with an IFE system. Those skilled in the art will appreciate that the docking station may include wireless communication in addition to connector 22 (or as an alternative to connector 22 if power is not required to be supplied to the media player).

Moveable clamping members 24 are also provided in recess 26. These contact side surfaces of the media player in use to allow the media player to be securely engaged with the base plate 20 by a clamping action. In one embodiment the clamping members 24 are interconnected by a centralisation mechanism such as a rack and pinion arrangement such that they remain equidistant from the connector 22. In use a user squeezes members 24 toward each other about the outer surface of a media player to engage the media player between members 24. The media player is removed by forcing members 24 apart and/or by sliding the media player out from between members 24. In one embodiment the clamping members make a frictional contact with the base plate 20 or the body 2, so that they retain the position into which they are manipulated by a user. In another embodiment the clamping members are biased toward each other, for example by use of a spring, to remain in contact with the media player. In this embodiment the clamping members are forced apart by a user to remove and/or insert a media player.

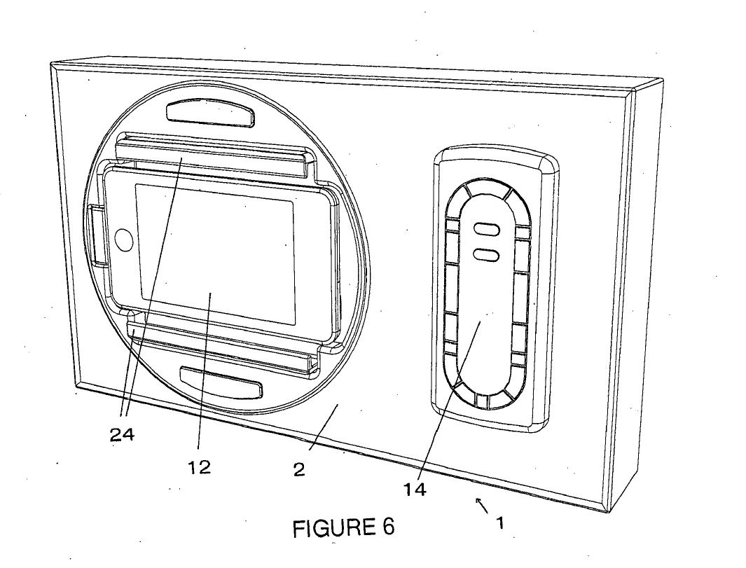

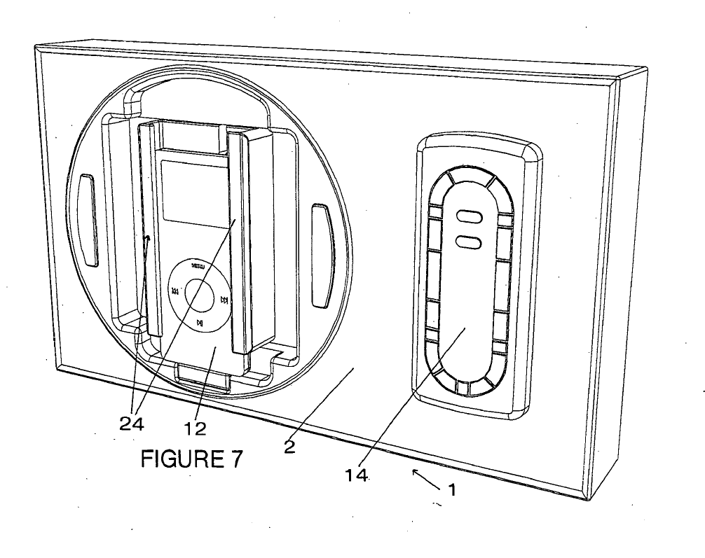

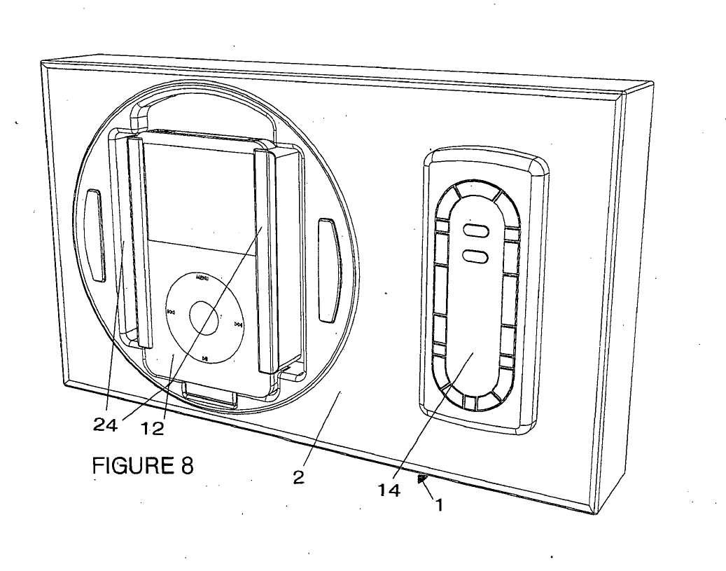

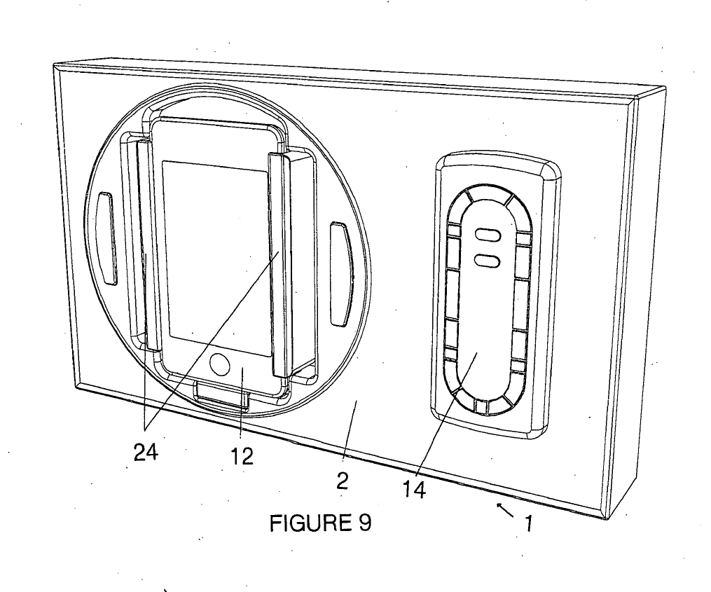

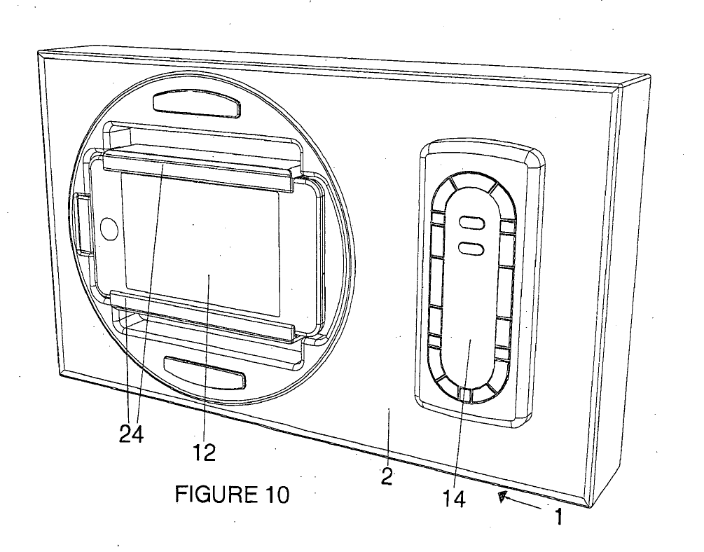

The clamping arrangement provided by members 24 and rotatable base plate 20 allows a wide variety of different types and sizes of medial player to be accommodated by the docking station 1, as shown in FIGS. 6 to 10.

Reference to any prior art in this specification is not, and should not be taken as, an acknowledgement or any form of suggestion that that prior art forms part of the common general knowledge in the field of endeavour in any country in the world.

Wherein the foregoing description reference has been made to integers or components having known equivalents thereof, those integers are herein incorporated as if individually set forth.

It should be noted that various changes and modifications to the presently preferred embodiments described herein will be apparent to those skilled in the art. Such changes and modifications may be made without departing from the spirit and scope of the invention and without diminishing its attendant advantages. It is therefore intended that such changes and modifications be included within the scope of the present invention.

1. A docking station for a media player, comprising a body having adjustable securing apparatus to allow a plurality of individual media players of different dimensions to be selectively secured to the body.

2. A docking station as claimed in claim 1 wherein the body or the securing apparatus allow a media player to be electrically coupled to the docking station.

3. A docking station as claimed in claim 1 wherein the securing means comprises a clamp.

4. A docking station as claimed in claim 1 wherein the securing apparatus is rotatable relative to the body to allow a media player to be disposed at a desired angular orientation relative to the body.

5. A docking station as claimed in claim 1 wherein the docking station includes a controller.

6. A docking station as claimed in claim 1 wherein the docking station includes a display screen.

7. A docking station as claimed in claim 1 wherein the docking station communicates with a remote display.

8. A docking station as claimed in claim 1 wherein the docking station includes shock absorption apparatus.

9. A passenger seat, the seat comprising a recess therein and a docking station according to claim 1 provided within the recess.
